(19) United States
(12) Patent Application Publication
(10) Pub. No.: US 2012/0126201 A1
(43) Pub. Date: May 24, 2012

(54) GALLIUM NITRIDE LED DEVICES WITH PITTED LAYERS AND METHODS FOR MAKING THEREOF

(76) Inventor: Heng Liu, Sunnyvale, CA (US)

(21) Appl. No.: 13/011,399

(22) Filed: Jan. 21, 2011

Related U.S. Application Data
(60) Provisional application No. 61/416,634, filed on Nov. 23, 2010.

(51) Int. Cl. H01L 33/06; H01L 33/58

(52) U.S. Cl. 257/13; 438/29; 257/E33.008; 257/E33.025; 257/E33.067

(57) ABSTRACT

Light-emitting diode device and method for making thereof. The device includes an n-type layer including a first surface and associated with a first thickness, and a pitted layer on the first surface. The pitted layer includes a second surface and associated with a second thickness ranging from 500 Å to 3000 Å. Additionally, the device includes an active layer on the second surface, the active layer being associated with a third thickness ranging from 10 Å to 20 Å, and a p-type layer on the active layer. The n-type layer is associated with a defect density at the first surface, and the defect density ranges from 1×10⁹ cm⁻² to 1×10¹⁰ cm⁻². The pitted layer is associated with at least a plurality of pits.

### 1. CROSS-REFERENCES TO RELATED APPLICATIONS

This application claims priority to U.S. Provisional No. 61/416,634, filed Nov. 23, 2010, commonly assigned and incorporated by reference herein for all purposes.

### 2. BACKGROUND OF THE INVENTION

The present invention is directed to semiconductor devices and fabrication methods. More particularly, the invention provides structures and methods using pitted layers in semiconductor devices. Merely by way of example, the invention has been applied to light-emitting diodes. But it would be recognized that the invention has a much broader range of applicability.

A light-emitting diode (LED) has been widely used as a light source. If the LED is forward biased, some electrons usually recombine with holes within the diode, thus emitting light. The color of the light often is determined by the energy gap that is associated with the LED. When used as a light source, the LED can provide significant advantages over incandescent light sources.

FIG. 1 is a simplified diagram showing a conventional LED device. The LED device 1100 includes a substrate 1102, an n-type layer 1110, an active layer 1125 and a p-type layer 1130. Additionally, a contact region 1115 and a contact region 1135 are formed on the n-type layer 1110 and the p-type layer 1130, respectively, and make electrical contacts to the n-type layer 1110 and the p-type layer 1130 respectively. If a proper voltage is applied to the contact regions 1115 and 1135, some electrons may be injected from the n-type layer 1110 into the active layer 1125, and the injected electrons may combine with holes in the active layer 1125. The electron-hole combination in the active layer can generate photons that are emitted from the LED device 1100.

Often, sapphire can be used for making the substrate 1102. Additionally, the n-type layer 1110 is made of AlGaN doped with Si, or GaN doped with Si. Moreover, the p-type layer 1130 is made of AlGaN doped with Mg, or GaN doped with Mg. Also, the light-emitting layer 1125 may include a single quantum well or multiple quantum wells that are formed with at least an InGaN/GaN superlattice.

In some cases, a series and/or parallel LED array is formed on a substrate that is either insulating or highly resistive (e.g., a sapphire substrate, a silicon carbide substrate, or a III-nitride substrate such as a gallium nitride substrate or an aluminum nitride substrate). The individual LED devices often are separated from each other by trenches but are electrically connected by interconnects deposited on the array. For example, before deposition for interconnects, a dielectric material is deposited over the LED array, and then patterned and removed in places to open contact holes to the n-type layer and the p-type layer, such that the dielectric material is left in trench between the individual LED devices and on the mesa walls between the exposed p-type layer and the exposed n-type layer of each LED device. This use of dielectric material can improve electrical isolation of individual LED devices.

But conventional LED devices often have limited efficiency; hence it is highly desirable to improve structures and fabrication techniques of LED devices.

### 3. BRIEF SUMMARY OF THE INVENTION

The present invention is directed to semiconductor devices and fabrication methods. More particularly, the invention provides structures and methods using pitted layers in semiconductor devices. Merely by way of example, the invention has been applied to light-emitting diodes. But it would be recognized that the invention has a much broader range of applicability.

According to one embodiment, a light-emitting diode device includes an n-type layer including a first surface and associated with a first thickness, and a pitted layer on the first surface. The pitted layer includes a second surface and associated with a second thickness ranging from 500 Å to 3000 Å. Additionally, the device includes an active layer on the second surface, the active layer being associated with a third thickness ranging from 10 Å to 20 Å, and a p-type layer on the active layer. The n-type layer is associated with a defect density at the first surface, and the defect density ranges from 1×10⁹ cm⁻² to 1×10¹⁰ cm⁻². The pitted layer is associated with at least a plurality of pits, and each of the plurality of pits is related to a pit size ranging from 500 Å to 3000 Å at the second surface.

According to another embodiment, a light-emitting diode device includes an n-type layer including a first surface and associated with a first thickness, and a first pitted layer on the first surface. The first pitted layer includes a second surface and is associated with a second thickness ranging from 500 Å to 3000 Å. Additionally, the device includes a first active layer on the second surface, and the first active layer is associated with a third thickness ranging from 10 Å to 20 Å. Moreover, the device includes a first p-type layer on the first active layer, a tunneling layer on the first p-type layer, and a second pitted layer on the tunneling layer. The second pitted layer includes a third surface and associated with a fourth thickness ranging from 500 Å to 3000 Å. Also, the device includes a second active layer on the third surface, and the second active layer is associated with a fifth thickness ranging from 10 Å to 20 Å. Additionally, the device includes a second p-type layer on the second active layer. The n-type layer is associated with a defect density at the first surface, and the defect density ranges from 1×10⁹ cm⁻² to 1×10¹⁰ cm⁻². The first pitted layer is associated with at least a first plurality of pits, and each of the first plurality of pits is related to a first pit size ranging from 500 Å to 3000 Å at the second surface. The second pitted layer is associated with at least a second plurality of pits, and each of the second plurality of pits is related to a second pit size ranging from 500 Å to 3000 Å at the third surface.

According to yet another embodiment, a method for making a light-emitting diode device includes depositing an n-type layer so that the n-type layer includes a first surface and is associated with a first thickness, and depositing a first pitted layer on the first surface so that the first pitted layer includes a second surface and is associated with a second thickness ranging from 500 Å to 3000 Å. Additionally, the method includes forming a first active layer on the second surface so that the first active layer is associated with a third thickness ranging from 10 Å to 20 Å, and forming a first p-type layer on the first active layer. The n-type layer is further associated with a defect density at the first surface, and the defect density ranges from 1×10⁹ cm⁻² to 1×10¹⁰ cm⁻². The first pitted layer is further associated with at least a first plurality of pits, and each of the first plurality of pits is related to a first pit size ranging from 500 Å to 3000 Å at the second surface.

Many benefits are achieved by way of the present invention over conventional techniques. Some embodiments of the present invention provide a GaN LED structure that has a simpler structure than some conventional LED structures. Certain embodiments of the present invention provide a GaN LED structure that takes much less time to fabricate than certain conventional LED structures. Some embodiments of the present invention provide a GaN LED structure that achieves a high peak value for internal quantum efficiency by effectively using a pitted layer.

Depending upon embodiment, one or more of these benefits may be achieved. These benefits and various additional objects, features and advantages of the present invention can be fully appreciated with reference to the detailed description and accompanying drawings that follow.

### 4. BRIEF DESCRIPTION OF THE DRAWINGS

FIG. 1 is a simplified diagram showing a conventional LED device.

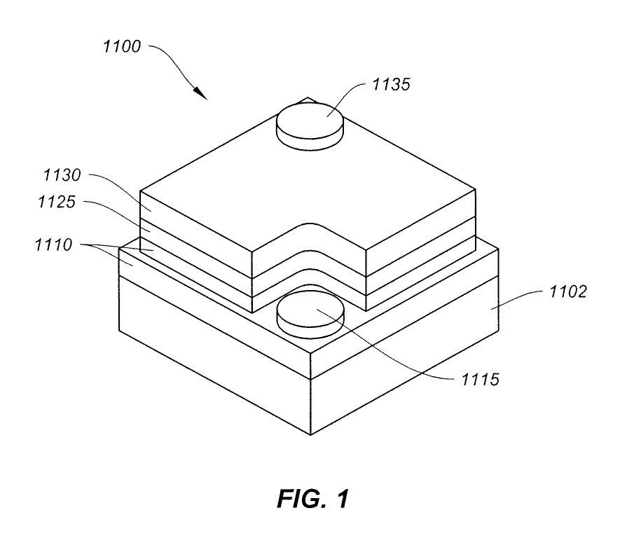

FIG. 2 is a simplified diagram showing a GaN LED structure with a pitted layer according to an embodiment of the present invention.

FIG. 3 is a simplified diagram showing defect density as a function of layer thickness for a Si-doped GaN layer.

FIG. 4 is a simplified diagram showing pit size as a function of layer thickness.

FIGS. 5(A), (B) and (C) are simplified diagrams showing various shapes of pits for the pitted layer as a part of the GaN LED structure according to an embodiment of the present invention.

FIGS. 6(A), (B) and (C) are simplified diagrams showing formation of an active layer on a pitted layer as a function of deposition time.

FIGS. 7(A) and (B) are simplified diagrams showing formation of an active layer on a pitted layer as a function of pit density.

FIG. 8 is a simplified diagram showing a chip with multiple GaN LED structures according to an embodiment of the present invention.

FIG. 9 is a simplified diagram showing a GaN LED structure with a pitted layer according to another embodiment of the present invention.

### 5. DETAILED DESCRIPTION OF THE INVENTION

The present invention is directed to semiconductor devices and fabrication methods. More particularly, the invention provides structures and methods using pitted layers in semiconductor devices. Merely by way of example, the invention has been applied to light-emitting diodes. But it would be recognized that the invention has a much broader range of applicability.

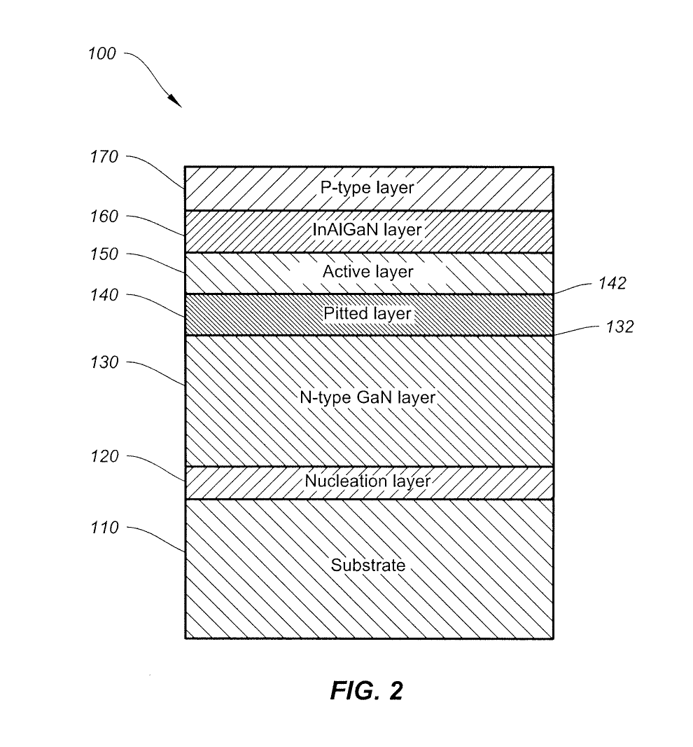

FIG. 2 is a simplified diagram showing a GaN LED structure with a pitted layer according to an embodiment of the present invention. This diagram is merely an example, which should not unduly limit the scope of the claims. One of ordinary skill in the art would recognize many variations, alternatives, and modifications. The GaN LED structure 100 includes a substrate 110, a nucleation layer 120, an n-type GaN layer 130, a pitted layer 140, an active layer 150, an InₓAl_{y}Ga_{z}N layer 160, and a p-type layer 170. For example, x+y+z=1, 0≦x≦1, 0≦y≦1, and 0≦z≦1. In another example, the active layer 150 has a bandgap that is smaller than the pitted layer 140 and the InₓAl_{y}Ga_{z}N layer 160. In yet another example, the active layer 150 is a quantum well layer, which forms a quantum well with the pitted layer 140 and the InₓAl_{y}Ga_{z}N layer 160.

As shown in FIG. 2, the LED structure 100 includes with the substrate 110. For example, the substrate 110 is a C-plane sapphire substrate or an A-plane sapphire substrate. In another example, the substrate 110 is a SiC substrate or a Si substrate. In yet another example, a round c-plane sapphire substrate with slightly tilted angle and a diameter that ranges from 2 to 4 inches is used as the substrate 110.

According to one embodiment, the nucleation layer 120 is formed on the substrate 110. For example, the nucleation layer 120 is deposited onto the substrate 110 at a temperature ranging from 400° C. to 900° C. with metal-organic sources and NH₃ introduced into a process chamber, and the pressure inside of the process chamber is less than one atmospheric pressure or ranges from 100 torr to 500 torr. In another example, after the nucleation layer 120 is deposited, an anneal at a temperature ranging from 1000° C.-1100° C. (such as at 1050° C.) is performed under a NH₃ flow to crystallize the nucleation layer 120 because the nucleation layer 120 previously deposited at lower temperatures is amorphous and/or polycrystalline. In yet another example, if the substrate 110 is the C-plane sapphire substrate or the A-plane sapphire substrate, the nucleation layer 120 is comprised of GaN, AlN, and/or AlGaN with thickness ranging from 200 Å-400 Å, such as being 250 Å. In yet another example, if the substrate 110 is the SiC substrate or the Si substrate, the nucleation layer 120 is comprised of AlN and/or AlGaN with thickness as much as several thousands of angstroms.

According to another embodiment, the n-type GaN layer 130 is doped with Si and deposited on the nucleation layer 120. For example, the deposition is performed in a MOCVD deposition chamber with a TMG gas (or a TEG gas), a NH₃ gas, and a dopant gas such as silane (SiH₄) at a temperature above 1000° C., such as at 1050° C. In another example, the electron concentration of the GaN layer 130 that is doped with Si ranges from 5×10¹⁸ cm⁻³-1×10¹⁹ cm⁻³. In yet another example, the thickness of the GaN layer 130 ranges from 1 μm-2 μm. In yet another example, the defect density of the GaN layer 130 ranges from 5×10⁹ cm⁻²-1×10¹⁰ cm⁻² at the surface 132.

As discussed above and further emphasized here, FIG. 2 is merely an example, which should not unduly limit the scope of the claims. One of ordinary skill in the art would recognize many variations, alternatives, and modifications. In one embodiment, a thin undoped GaN layer, about 0.5 μm-1 μm in thickness, is deposited on the nucleation layer 120 before the Si-doped GaN layer 130 is formed.

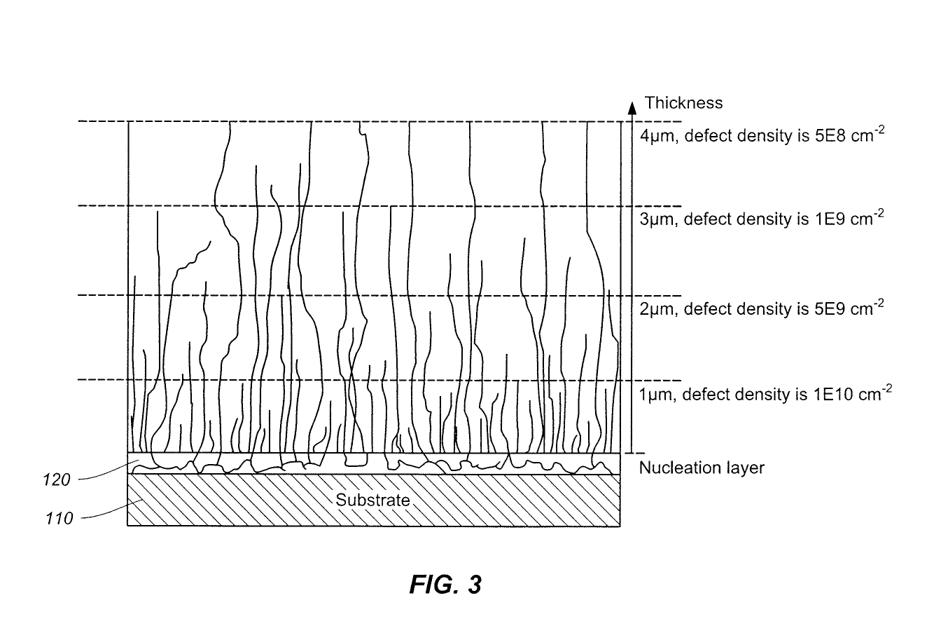

FIG. 3 is a simplified diagram showing defect density as a function of layer thickness for a Si-doped GaN layer. In one embodiment, a Si-doped GaN layer is formed on the nucleation layer 120 located on the substrate 110. In another embodiment, the substrate 110 is comprised of sapphire, and the nucleation layer 120 is comprised of GaN with thickness ranging from 200 Å-400 Å. In yet another embodiment, there exists a large lattice mismatch between GaN and sapphire; therefore, certain defects such as threading dislocations can form at the GaN/sapphire interface and these defects can propagate along the deposition direction.

As shown in FIG. 3, the defect density of the Si-doped GaN layer decreases with the increasing thickness. For example, the defect density is about 1×10¹⁰ cm⁻² at 1-μm thickness, about 5×10⁹ cm⁻² at 2-μm thickness, about 1×10⁹ cm⁻² at 3-μm thickness, and about 5×10⁸ cm⁻² at 4-μm thickness. In another example, the Si-doped GaN layer is used as the n-type GaN layer 130. According to one embodiment, the thickness of the Si-doped GaN layer 130 is selected to range from 1 μm-2 μm. According to another embodiment, the defect density of the Si-doped GaN layer 130 ranges from 5×10⁹ cm⁻²-1×10¹⁰ cm⁻² at the surface 132.

Returning to FIG. 2, after the n-type GaN layer 130 is deposited, the pitted layer 140 is formed. For example, the pitted layer 140 is deposited at a temperature ranging from 600° C.-800° C. In another example, the electron concentration of the pitted layer 140 is lower than 1×10¹⁸ cm⁻³. In yet another example, the thickness of the pitted layer 140 ranges from 500 Å-3000 Å or from 500 Å-1000 Å.

In yet another example, the pitted layer 140 is a GaN layer, an InGaN layer, or an InGaN/GaN superlattice. In yet another example, a TMG gas and/or a TEG gas is used as a source for Ga, a NH₃ gas is used as a source for nitrogen, and if needed, a TMI gas is used as a source for In, in order to deposit the pitted layer 140.

In one embodiment, the term “pitted” means a surface 142 of the layer 140 contains certain pits. For example, formation of the pits is associated with the dislocations that propagate to a surface 132 of the GaN layer 130. In another example, when GaN or InGaN is deposited at a low temperature ranging from 600° C.-800° C. for the layer 140, some low-deposition-rate planes form as the deposition progresses. In yet another example, these low-deposition-rate planes share the same origin of a particular dislocation and are oblique to the normal direction, resulting in a six-fold symmetry hexagonal pit. In yet another example, the pit density at the surface 142 of the layer 140 increases with the increasing defect density, such as the increasing dislocation density, at the interface between the layer 130 and the layer 140 (e.g., at the surface 132 of the GaN layer 130).

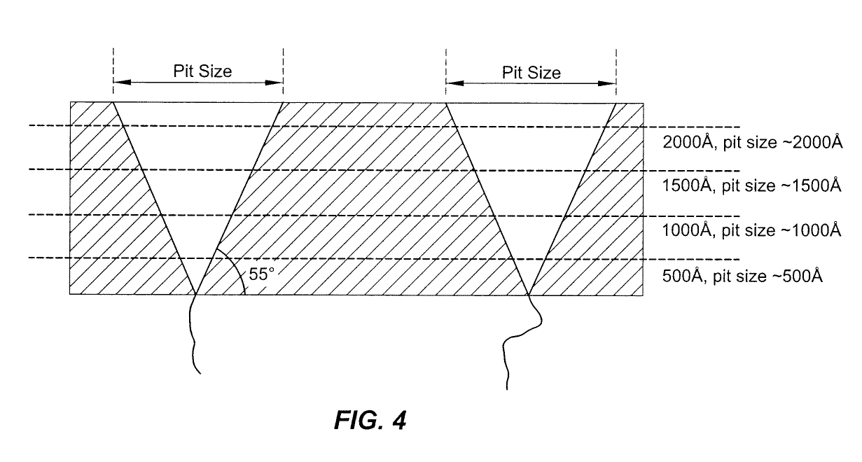

FIG. 4 is a simplified diagram showing pit size as a function of layer thickness. In one embodiment, given the same pit origin, the pit size increases with the increasing layer thickness. For example, the pit size measures the largest dimension of a pit opening at a given surface. In another example, if a pit originates from the bottom surface of the layer, the pit size is about 500 Å at 500-Å thickness, about 1000 Å at 1000-Å thickness, about 1500 Å at 1500-Å thickness, and about 2000 Å at 2000-Å thickness. In another example, at the same thickness, the pit size for pits that originate above the bottom surface of the layer is smaller than the pit size for pits that original at the bottom surface of the layer. According to one embodiment, the thickness of the pitted layer 140 is selected to range from 500 Å-3000 Å or 500 Å-1000 Å, and the pit size for certain pits ranges from 500 Å-3000 Å or 500 Å-1000 Å at the surface 142 of the layer 140 respectively.

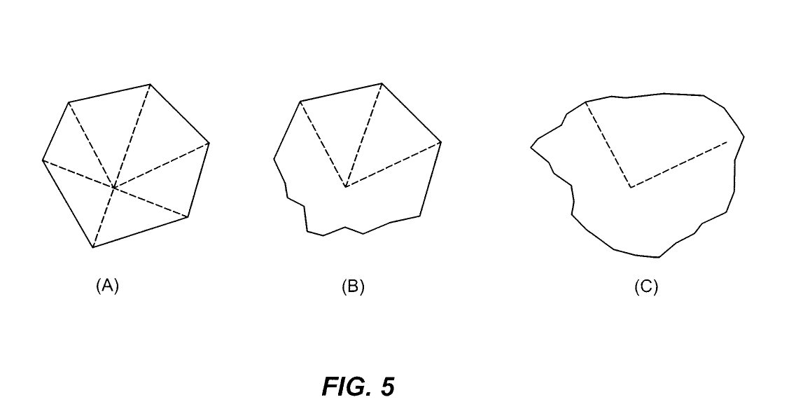

FIGS. 5(A), (B) and (C) are simplified diagrams showing various shapes of pits for the pitted layer 140 as a part of the GaN LED structure 100 according to an embodiment of the present invention. These diagrams are merely examples, which should not unduly limit the scope of the claims. One of ordinary skill in the art would recognize many variations, alternatives, and modifications.

As shown in FIG. 5(A), a pit for the layer 140 has a hexagonal shape with six planes that are merged at one point below the surface 142. As shown in FIG. 5(B), a pit for the layer 140 has a portion of an irregular shape and a portion of a hexagonal shape with less than six planes that are merged at one point below the surface 142. As shown in FIG. 5(C), a pit for the layer 140 is formed with some portions of crystallographic planes.

Returning to FIG. 2, on the pitted layer 140, the active layer 150 is formed. In one embodiment, the active layer 150 has a bandgap that is smaller than the pitted layer 140. In another embodiment, the active layer 150 is comprised of InGaN. In yet another embodiment, the active layer 150 has a thickness ranging from 10 Å-20 Å, such as being 15 Å. In yet another embodiment, the active layer 150 is undoped or lightly doped to n-type or p-type.

For example, the active layer 150 is comprised of InGaN and deposited by flowing TMG (or TEG), TMI, and NH₃ gases into a MOCVD deposition chamber. In another example, the deposition temperature ranges from 600° C.-800° C. According to one embodiment, for a blue-emission LED structure, the deposition temperature is about 720° C., and the deposition pressure is between 200 torr-350 torr. According to another embodiment, for a green-emission LED structure, the deposition pressure is also between 200 torr-350 torr, but the deposition temperature is about 30-50° C. lower than the deposition temperature for the blue-emission LED structure. In yet another example, the deposition time of the active layer 150 ranges from 15 seconds to 120 seconds, depending on the growth rate.

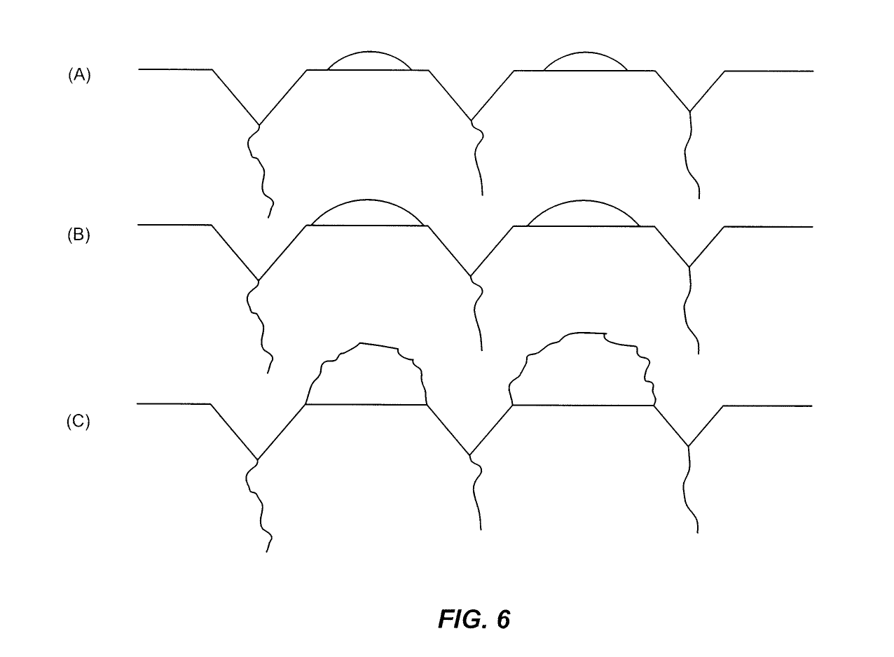

FIGS. 6(A), (B) and (C) are simplified diagrams showing formation of an active layer on a pitted layer as a function of deposition time. In one embodiment, as shown in FIGS. 6(A), (B) and (C), the InGaN alloy tends to grow outside and away from the pits of the pitted layer. In another embodiment, FIGS. 6(A), (B) and (C) describe certain properties of the active layer with increasing deposition time.

For example, as shown in FIG. 6(A), at a given growth rate, with a shorter deposition time, thinner and smaller InGaN islands are formed, and the resulting active layer has a higher quality due to less stress. In another example, as FIG. 6(B), with a longer deposition time, thicker and larger InGaN islands are formed, and the resulting active layer has a lower quality due to larger stress. In yet another example, as shown in FIG. 6(C), with an even longer deposition time, even thicker but not much larger InGaN islands are formed with deteriorating surfaces, and the resulting active layer has an even lower quality due to stress that is even larger and leads to phase separation and In and Ga metal formation. According to one embodiment, the active layer 150 is formed according to FIG. 6(A). According to another embodiment, the deposition time for the active layer 150 ranges from 15 seconds to 120 seconds, depending on the growth rate.

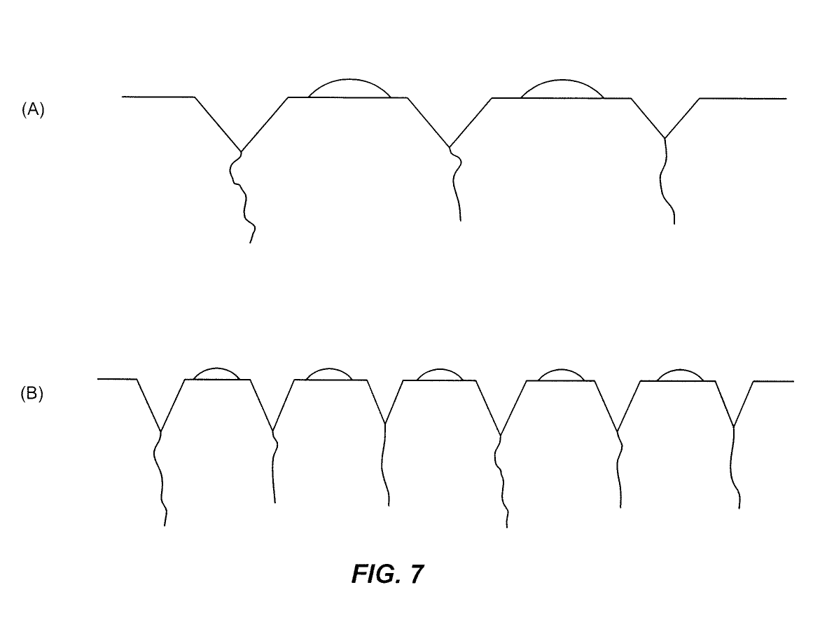

FIGS. 7(A) and (B) are simplified diagrams showing formation of an active layer on a pitted layer as a function of pit density. For example, as shown in FIG. 7(A), with lower pit density at the top surface of the pitted layer and with the same deposition time and the same growth rate, larger and thicker InGaN islands are formed, and the resulting active layer has a lower quality due to larger stress. In another example, as shown in FIG. 7(B), with higher pit density at the top surface of the pitted layer and with the same deposition time, smaller and thinner InGaN islands are formed, and the resulting active layer has a higher quality due to less stress.

According to one embodiment, the pitted layer 140 is formed according to FIGS. 4 and 7(B). According to another embodiment, the pitted layer 140 has a pit density ranging from 1×10⁹ cm⁻² to 3×10¹⁰ cm⁻² for pits with pit sizes ranging from 500 Å-3000 Å at the surface 142, depending on the thickness of the pitted layer 140.

Returning to FIG. 2, as discussed above, according to certain embodiments, the pitted layer 140 and the active layer 150 are formed according to FIGS. 4, 6(A) and 7(B). In another embodiment, the active layer 150 is replaced by one or more GaN/InGaN double-layer structures in order to form a multiple quantum well structure in the LED device. For example, the multiple quantum well structure includes two or more quantum wells, each of which uses an InGaN layer as the active layer, and the two or more quantum wells are separated by one or more GaN layers as barrier layers. In another example, the InGaN layer as the active layer has a thickness ranging from 10 Å-20 Å, such as being 15 Å. In yet another example, each of the one or more GaN layers as barrier layers has a thickness ranging from 30 Å-200 Å. In yet another example, some indium is added into the one or more GaN layers as barrier layers, so long as the bandgap of the one or more GaN layers as barrier layers remains larger than the bandgap of the InGaN layer as the active layer. In yet another example, the multiple quantum well structure is undoped or lightly doped to n-type or p-type. According to some embodiments, the first few GaN/InGaN double-layer structures are Si-doped to n-type with an electron concentration of about 5×10¹⁷ cm⁻³, and the last one or two GaN/InGaN double-layer structures are not doped.

According to another embodiment, on the active layer 150, the InₓAl_{y}Ga_{z}N layer 160 is formed. For example, the active layer 150 has a bandgap that is smaller than the InₓAl_{y}Ga_{z}N layer 160. In another example, x+y+z=1, 0≦x≦1, 0≦y≦1, and 0≦z≦1. In yet another example, the thickness of the InₓAl_{y}Ga_{z}N layer 160 ranges from 200 Å-1000 Å, such as being about 600 Å. In yet another example, the InₓAl_{y}Ga_{z}N layer 160 is doped to p-type with Mg.

In yet another example, the InₓAl_{y}Ga_{z}N layer 160 is deposited in a MOCVD deposition chamber. In one embodiment, a TMG gas and/or a TEG gas is used as a source for Ga, a TMI gas is used as a source for In, a TMA gas is used as a source for Al, and an NH₃ gas is used as a source for nitrogen in order to deposit the InₓAl_{y}Ga_{z}N layer 160. In another embodiment, the deposition temperature ranges from 900° C.-950° C. In yet another embodiment, the deposition pressure ranges from 50 torr-200 torr.

Additionally, on the InₓAl_{y}Ga_{z}N 160, the p-type layer 170 is formed according to one embodiment. For example, the layer 170 is comprised of GaN or InGaN, and is heavily doped with Mg. In another example, the thickness of the layer 170 ranges from 10 Å-100 Å. In yet another example, the deposition temperature ranges from 800° C.-930° C. In yet another example, the p-type layer 170 is used to provide an ohmic contact with an external electrode.

According to certain embodiments, the internal quantum efficiency of the GaN LED structure 100 depends on current density and reaches a peak efficiency value at a particular current density level. For example, the internal quantum efficiency is the ratio of the number of photons generated in the active layer 150 to the number of electrons injected into the active layer 150. In another example, regarding the internal quantum efficiency, the peak efficiency value of the GaN LED structure 100 ranges from 60%-95%, from 75%-95%, or from 85%-95%.

As discussed above and further emphasized here, FIG. 2 is merely an example, which should not unduly limit the scope of the claims. One of ordinary skill in the art would recognize many variations, alternatives, and modifications. In one embodiment, the substrate 110 is a Si substrate, such as a (111) Si substrate with a diameter that ranges from 2 to 12 inches. In another embodiment, an AlN layer or a high-Al-content AlGaN layer is deposited on the Si substrate, before an n-type GaN layer (e.g., the layer 130) is formed on the AlN layer or the high-Al-content AlGaN layer.

For example, the deposition of the AlN layer or the high-Al-content AlGaN layer is performed at a temperature ranging from 700° C.-900° C. by flowing a TMA gas, a TMG, and/or an NH₃ gas into an MOCVD deposition chamber with a deposition pressure that ranges from 50 torr-250 torr. In another example, the AlN layer or the high-Al-content AlGaN layer is about 5000-Å thick. In yet another example, a graded AlGaN layer with varying Ga and Al content is used so that the top surface of the layer is a GaN surface, on which an n-type GaN layer (e.g., the layer 130) is formed.

In yet another embodiment, subsequently, a pitted layer (e.g., the layer 140) is formed on the n-type GaN layer (e.g., the layer 130). Afterwards, an active layer (e.g., the layer 150), an InₓAl_{y}Ga_{z}N layer (e.g., the layer 160), and a p-type layer (e.g., the layer 170) are, for example, sequentially formed. Then, the LED structure goes through a Si substrate removal process because Si is an absorbing material to the blue or green emission from the LED according to certain embodiments. In yet another embodiment, the p-type layer 170 is bonded to another layer, and afterwards, the substrate 110 and the nucleation layer 120 are removed.

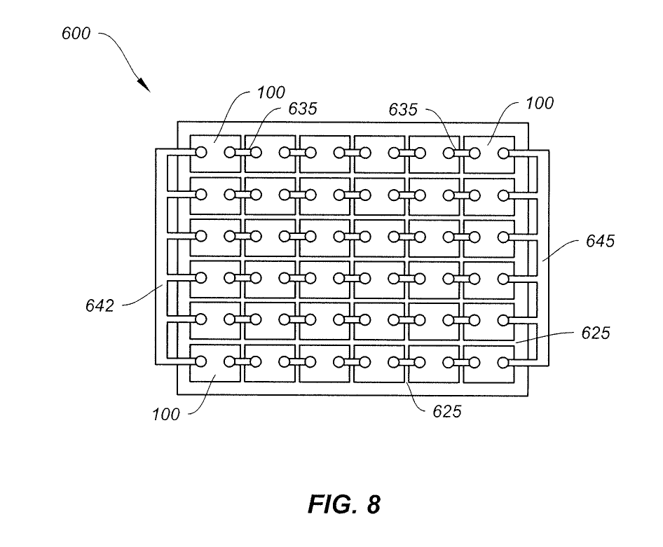

FIG. 8 is a simplified diagram showing a chip with multiple GaN LED structures 100 according to an embodiment of the present invention. This diagram is merely an example, which should not unduly limit the scope of the claims. One of ordinary skill in the art would recognize many variations, alternatives, and modifications.

As shown in FIG. 8, the chip 600 includes a substrate 625 where multiple LED structures 100 are formed and interconnected by metal traces 635 into a 6-by-6 mesa array. For example, the substrate 625 can be the substrate 110 on which the rest of the LED structure 100 is first formed, or the substrate 625 is a substrate to which the LED structure 100 is transferred after formation. In another example, each LED structure 100 has a mesa size of approximately 250 μm by 600 μm.

In one embodiment, each mesa LED structure 100 is driven at about 2 mA with a forward voltage of about 3V. In another embodiment, the electrical connection is made such that 6 mesa LED structures 100 are in series and 6 rows of LED structures 100 are in parallel with a common cathode at one end and a common anode at another end. In another embodiment, the chip 600 is driven at 12 mA and 18 V with an operating input power of 216 mW.

For example, the 6-by-6 mesa array can be scaled up for higher output power per chip by either scaling up the mesa size or increasing the number of mesa LED structures per chip. According to one embodiment, the chip 600 includes a 20-by-50 array with an operating voltage of 60 V and an operating current of 100 mA, and each of the LED structures 100 has a mesa size of 250 μm by 600 μm.

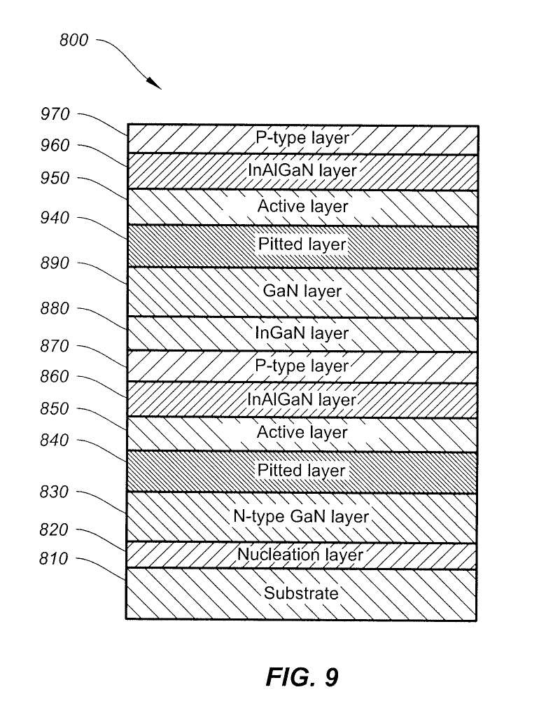

FIG. 9 is a simplified diagram showing a GaN LED structure with a pitted layer according to another embodiment of the present invention. This diagram is merely an example, which should not unduly limit the scope of the claims. One of ordinary skill in the art would recognize many variations, alternatives, and modifications. The GaN LED structure 800 includes a substrate 810, a nucleation layer 820, an n-type GaN layer 830, a pitted layer 840, an active layer 850, an InₓAl_{y}Ga_{z}N layer 860, a p-type layer 870, an InGaN layer 880, a GaN layer 890, a pitted layer 940, an active layer 950, an InₓAl_{y}Ga_{z}N layer 960, and a p-type layer 970.

For example, x+y+z=1, 0≦x≦1, 0≦y≦1, and 0≦z≦1. In another example, the active layer 850 has a bandgap that is smaller than the pitted layer 840 and the InₓAl_{y}Ga_{z}N layer 860. In yet another example, the active layer 850 is a quantum well layer, which forms a quantum well with the pitted layer 840 and the InₓAl_{y}Ga_{z}N layer 860. In yet another example, the active layer 950 has a bandgap that is smaller than the pitted layer 940 and the InₓAl_{y}Ga_{z}N layer 960. In yet another example, the active layer 950 is a quantum well layer, which forms a quantum well with the pitted layer 940 and the InₓAl_{y}Ga_{z}N layer 960.

In one embodiment, the substrate 810, the nucleation layer 820, the n-type GaN layer 830, the pitted layer 840, the active layer 850, the InₓAl_{y}Ga_{z}N layer 860, and the p-type layer 870 are substantially the same as the substrate 110, the nucleation layer 120, the n-type GaN layer 130, the pitted layer 140, the active layer 150, the InₓAl_{y}Ga_{z}N layer 160, and the p-type layer 170 respectively. In another embodiment, the pitted layer 940, the active layer 950, the InₓAl_{y}Ga_{z}N layer 960, and the p-type layer 970 are substantially the same as the pitted layer 140, the active layer 150, the InₓAl_{y}Ga_{z}N layer 160, and the p-type layer 170 respectively. In yet another embodiment, the GaN LED structure 800 is formed with an MOCVD process.

In yet another embodiment, the GaN LED structure 800 includes two or more LED structures that are stacked together. For example, each of the two or more stacked LED structures is similar to the LED structure 100. In another example, the two or more stacked LED structures emit light of the same color or different colors.

As shown in FIG. 9, between the p-type layer 870 and the pitted layer 940, there are two additional layers—the InGaN layer 880 and the GaN layer 890. According to one embodiment, the InGaN layer 880 is formed by deposition and heavily doped with Si to n-type. For example, the InGaN layer 880 is doped to n+. According to another embodiment, the InGaN layer 880 is only about 25 Å in thickness. For example, the InGaN layer 880 is used to reduce the voltage drop due to the reverse biased p-n junction. In another example, through at least the InGaN layer 880, some electrons move by tunneling from the p-type layer 870 to the GaN layer 890 or to the pitted layer 940.

In one embodiment, the GaN layer 890 is doped to n-type and is deposited on top of the InGaN layer 880. For example, the GaN layer 890 is deposited at a temperature above 1000° C. so that a smoother surface can be produced before the pitted layer 940 is deposited. In another embodiment, the GaN layer 890 is replaced by an InGaN layer that is formed on the InGaN layer 880. In yet another embodiment, the GaN layer 890 is not formed so that the pitted layer 940 is deposited directly on the InGaN layer 880, and, during and after the formation of the active layer 850 and/or the active layer 950, the GaN LED structure 800 is not heated to a temperature exceeding 980° C.

According to one embodiment, the LED structure 800 operates at a forward voltage that is twice as much as the LED structure 100; hence the vertical stacking increases the junction area with the cross-section size unchanged. For example, the LED structure 800 has a forward current of about 2 mA at a forward voltage of about 6 V. According to another embodiment, if the LED structures 100 are replaced by the LED structures 800 in FIG. 9, the size of the chip 600 can become half while still operating at the same voltage and current with only three mesa LED structures 800 in series for each row and with six rows in parallel.

As discuss above and further emphasized here, FIG. 9 is merely an example, which should not unduly limit the scope of the claims. One of ordinary skill in the art would recognize many variations, alternatives, and modifications. For example, one or more combinations of the layers 880, 890, 940, 950, 960 and 970 or one or more combinations of the layers 880, 940, 950, 960 and 970 are stacked on top of the p-type layer 970 to form the LED structures 800. In another example, photons generated in the active layer 950 correspond to a light color that is different from photons generated in the active layer 850.

In yet another example, referring to FIG. 9, after the p-type layer 870 is formed, a growth stop process is performed. In one embodiment, during the growth stop process, the reaction chamber for making the GaN LED structure 800 does not contain any NH₃ gas or H₂ gas. In another embodiment, during the growth stop process, the reaction chamber for making the GaN LED structure 800 contains the N₂ gas at a temperature ranging from 600-900° C. In yet another embodiment, the growth stop process is performed for about 5 to 30 minutes. In yet another embodiment, the growth stop process is performed either after the p-type layer 870 is formed but before the InGaN layer 880 is formed, or after both the p-type layer 870 and the InGaN layer 880 are formed. In yet another example, if one or more combinations of the layers 880, 890, 940, 950, 960 and 970, or one or more combinations of the layers 880, 940, 950, 960 and 970 are stacked on top of the p-type layer 970 to form the LED structures 800, the growth stop process is also performed for each of the one or more combinations of the layers 880, 890, 940, 950, 960 and 970, or each of the one or more combinations of the layers 880, 940, 950, 960 and 970.

According to certain embodiments, the LED structure 100 and/or the LED structure 800 can be used to make light bulbs as street lights and/or other applications. For example, the light bulbs each include one or more LED structures 100 and/or one or more LED structures 800. According to some embodiments, the chip 600 is used to make light bulbs as street lights and/or other applications. For example, the light bulbs each include one or more chips 600. In another example, regarding the external quantum efficiency, the peak efficiency value of the light bulb ranges from 55%-75%.

Many benefits are achieved by way of the present invention over conventional techniques. According to some embodiments, the GaN LED structure 100 has a simpler structure than some conventional LED structures. According to certain embodiments, the GaN LED structure 100 takes much less time to fabricate than certain conventional LED structures. According to some embodiments, the GaN LED structure 100 achieves a high peak value for internal quantum efficiency by effectively using the pitted layer 140.

For example, the defect density of the n-type GaN layer 130 is made high at the surface 132 in order to help raise the pit density at the surface 142 as shown in FIG. 3. In another example, using the high defect density at the surface 132, the thickness of the pitted layer 140 is limited in order to ensure a high pit density at the surface 142, as shown in FIGS. 4 and 7(B). In yet another example, with assistance of high pit density at the surface 142, the thickness of the active layer 150 is limited in order to improve quality of the active layer 150 and hence also improve the quantum efficiency of the GaN LED structure 100, as shown in FIG. 6(A).

As shown in FIG. 3, the n-type GaN layer 130 is limited to only 1 μm-2 μm in thickness, so that the defect density of the n-type GaN layer 130 is made high at the surface 132, ranging from 5×10⁹ cm⁻²-1×10¹⁰ cm⁻² according to certain embodiments. As shown in FIGS. 4 and 7(B), in addition to the high defect density at the surface 132, the thickness of the pitted layer 140 is also limited to only 500 Å-1000 Å so that a high pit density ranging from 1×10⁹ cm⁻² to 3×10¹⁰ cm⁻² can be obtained for pits with pit sizes ranging from 500 Å-1000 Å at the surface 142 according to some embodiments. As shown in FIG. 6(A), on the surface 142 with high pit density, the active layer 150 is limited to only 10 Å-20 Å in thickness in order to improve quality of the active layer 150, hence also improving the quantum efficiency of the GaN LED structure 100, according to certain embodiments.

According to another embodiment, a light-emitting diode device includes an n-type layer including a first surface and associated with a first thickness, and a pitted layer on the first surface. The pitted layer includes a second surface and associated with a second thickness ranging from 500 Å to 3000 Å. Additionally, the device includes an active layer on the second surface, the active layer being associated with a third thickness ranging from 10 Å to 20 Å, and a p-type layer on the active layer. The n-type layer is associated with a defect density at the first surface, and the defect density ranges from 1×10⁹ cm⁻² to 1×10¹⁰ cm⁻². The pitted layer is associated with at least a plurality of pits, and each of the plurality of pits is related to a pit size ranging from 500 Å to 3000 Å at the second surface. For example, the light-emitting diode device is implemented according to at least FIG. 2.

According to yet another embodiment, a light-emitting diode device includes an n-type layer including a first surface and associated with a first thickness, and a first pitted layer on the first surface. The first pitted layer includes a second surface and is associated with a second thickness ranging from 500 Å to 3000 Å. Additionally, the device includes a first active layer on the second surface, and the first active layer is associated with a third thickness ranging from 10 Å to 20 Å. Moreover, the device includes a first p-type layer on the first active layer, a tunneling layer on the first p-type layer, and a second pitted layer on the tunneling layer. The second pitted layer includes a third surface and associated with a fourth thickness ranging from 500 Å to 3000 Å. Also, the device includes a second active layer on the third surface, and the second active layer is associated with a fifth thickness ranging from 10 Å to 20 Å. Additionally, the device includes a second p-type layer on the second active layer. The n-type layer is associated with a defect density at the first surface, and the defect density ranges from 1×10⁹ cm⁻² to 1×10¹⁰ cm⁻². The first pitted layer is associated with at least a first plurality of pits, and each of the first plurality of pits is related to a first pit size ranging from 500 Å to 3000 Å at the second surface. The second pitted layer is associated with at least a second plurality of pits, and each of the second plurality of pits is related to a second pit size ranging from 500 Å to 3000 Å at the third surface. For example, the light-emitting diode device is implemented according to at least FIG. 9.

According to yet another embodiment, a method for making a light-emitting diode device includes depositing an n-type layer so that the n-type layer includes a first surface and is associated with a first thickness, and depositing a first pitted layer on the first surface so that the first pitted layer includes a second surface and is associated with a second thickness ranging from 500 Å to 3000 Å. Additionally, the method includes forming a first active layer on the second surface so that the first active layer is associated with a third thickness ranging from 10 Å to 20 Å, and forming a first p-type layer on the first active layer. The n-type layer is further associated with a defect density at the first surface, and the defect density ranges from 1×10⁹ cm⁻² to 1×10¹⁰ cm⁻². The first pitted layer is further associated with at least a first plurality of pits, and each of the first plurality of pits is related to a first pit size ranging from 500 Å to 3000 Å at the second surface. For example, the method for making a light-emitting diode device is implemented according to at least FIG. 2.

In another example, during and after the process for forming a first active layer on the second surface, the method does not include any process that is performed at a temperature exceeding 980° C. In yet another example, the method further includes providing a substrate, and forming a nucleation layer on the substrate so that the nucleation layer includes a third surface and is associated with a fourth thickness ranging from 200 Å to 400 Å. In yet another example, the method further includes removing the substrate and removing the nucleation layer. In yet another example, the second thickness ranges from 500 Å to 1000 Å, and the first pit size ranges from 500 Å to 1000 Å at the second surface. In yet another example, the defect density ranges from 5×10⁹ cm⁻² to 1×10¹⁰ cm⁻².

In yet another example, the method further includes forming a tunneling layer on the first p-type layer, depositing a second pitted layer on the tunneling layer so that the second pitted layer including a third surface and associated with a fourth thickness ranging from 500 Å to 3000 Å, forming a second active layer on the third surface so that the second active layer being associated with a fifth thickness ranging from 10 Å to 20 Å, and forming a second p-type layer on the second active layer. The second pitted layer is associated with at least a second plurality of pits, and each of the second plurality of pits is related to a second pit size ranging from 500 Å to 3000 Å at the third surface. In yet another example, during and after the process for forming a second active layer on the third surface, the method does not include any process that is performed at a temperature exceeding 980° C. In yet another example, the fourth thickness ranges from 500 Å to 1000 Å, and the second pit size ranges from 500 Å to 1000 Å at the third surface. In yet another example, the process for forming a tunneling layer includes depositing an InGaN layer doped with Si. In yet another example, the method further includes depositing a GaN layer located between the tunneling layer and the second pitted layer. In yet another example, the method further includes, after the process for forming a first p-type layer is performed, a growth stop process is performed, for example, before or after the process for forming a tunneling layer is performed. In yet another example, the method for making a light-emitting diode device is implemented according to at least FIG. 9.

As discuss above and further emphasized here, FIGS. 2 and 9 are merely examples, which should not unduly limit the scope of the claims. One of ordinary skill in the art would recognize many variations, alternatives, and modifications. For example, if a layer is described as being on another layer, the layer can be either directly or indirectly on the another layer.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

1. A light-emitting diode device, the device comprising:
an n-type layer including a first surface and associated with a first thickness;
a pitted layer on the first surface, the pitted layer including a second surface and associated with a second thickness ranging from 500 Å to 3000 Å;
an active layer on the second surface, the active layer being associated with a third thickness ranging from 10 Å to 20 Å; and
a p-type layer over the active layer;
wherein:
the n-type layer is associated with a defect density at the first surface, the defect density ranging from 1×10⁹ cm⁻² to 1×10¹⁰ cm⁻²; and
the pitted layer is associated with at least a plurality of pits, each of the plurality of pits being related to a pit size ranging from 500 Å to 3000 Å at the second surface.

2. The device of claim 1 wherein the defect density ranges from 5×10⁹ cm⁻² to 1×10¹⁰ cm⁻².

3. The device of claim 1 wherein:
the second thickness ranges from 500 Å to 1000 Å; and
the pit size ranges from 500 Å to 1000 Å at the second surface.

4. The device of claim 3 wherein the pitted layer is associated with a pit density ranging from 1×10⁹ cm⁻² to 3×10¹⁰ cm⁻² for pits with pit sizes ranging from 500 Å to 1000 Å at the second surface.

5. The device of claim 1 is characterized by an internal quantum efficiency, wherein:
the internal quantum efficiency is associated with a peak efficiency value; and
the peak efficiency value ranges from 60% to 95%.

6. The device of claim 5 wherein the peak efficiency value ranges from 75% to 95%.

7. The device of claim 1 wherein the n-type layer includes GaN doped with silicon.

8. The device of claim 1 wherein the pitted layer includes at least one selected from a group consisting of a GaN layer, an InGaN layer, and an InGaN/GaN superlattice.

9. The device of claim 1 wherein the active layer comprises InGaN.

10. The device of claim 1, and further comprising:
an InₓAl_{y}Ga_{z}N layer located between the active layer and the p-type layer;
wherein:
x+y+z=1;
0≦x≦1;
0≦y≦1; and
0≦z≦1.

11. The device of claim 1 wherein the p-type layer includes at least one selected from a group consisting of GaN and InGaN, doped with Mg.

12. The device of claim 1 is characterized by a forward current of about 2 mA at a forward voltage of about 3V.

13. The device of claim 1, and further comprising:
a substrate; and
a nucleation layer on the substrate, the nucleation layer including a third surface and associated with a fourth thickness ranging from 200 Å to 400 Å;
wherein the n-type layer is located over the third surface.

14. The device of claim 13, and further comprising:
an un-doped GaN layer located between the nucleation layer and the n-type layer;
wherein the n-type layer includes GaN doped with silicon.

15. A light-emitting diode device, the device comprising:
an n-type layer including a first surface and associated with a first thickness;
a first pitted layer on the first surface, the first pitted layer including a second surface and associated with a second thickness ranging from 500 Å to 3000 Å;
a first active layer on the second surface, the first active layer being associated with a third thickness ranging from 10 Å to 20 Å;
a first p-type layer over the first active layer;
a tunneling layer on the first p-type layer;
a second pitted layer over the tunneling layer, the second pitted layer including a third surface and associated with a fourth thickness ranging from 500 Å to 3000 Å;
a second active layer on the third surface, the second active layer being associated with a fifth thickness ranging from 10 Å to 20 Å; and
a second p-type layer en-over the second active layer;
wherein:
the n-type layer is associated with a defect density at the first surface, the defect density ranging from 1×10⁹ cm⁻² to 1×10¹⁰ cm⁻²;
the first pitted layer is associated with at least a first plurality of pits, each of the first plurality of pits being related to a first pit size ranging from 500 Å to 3000 Å at the second surface; and
the second pitted layer is associated with at least a second plurality of pits, each of the second plurality of pits being related to a second pit size ranging from 500 Å to 3000 Å at the third surface.

16. The device of claim 15 wherein:
the second thickness ranges from 500 Å to 1000 Å;
the fourth thickness ranges from 500 Å to 1000 Å;
the first pit size ranges from 500 Å to 1000 Å at the second surface; and
the second pit size ranges from 500 Å to 1000 Å at the third surface.

17. The device of claim 15 wherein the defect density ranges from 5×10⁹ cm⁻² to 1×10¹⁰ cm⁻².

18. The device of claim 15 wherein the tunneling layer comprises InGaN doped with Si.

19. The device of claim 15 wherein the tunneling layer is associated with a layer thickness of about 25 Å.

20. The device of claim 15, and further comprising a GaN layer located between the tunneling layer and the second pitted layer.

21. The device of claim 15 is characterized by an internal quantum efficiency, wherein:
the internal quantum efficiency is associated with a peak efficiency value; and
the peak efficiency value ranges from 60% to 95%.

22. The device of claim 21 wherein the peak efficiency value ranges from 75% to 95%.

23. The device of claim 15 is characterized by a forward current of about 2 mA at a forward voltage of about 6V.

24. The device of claim 15, and further comprising:
a substrate; and
a nucleation layer on the substrate, the nucleation layer including a fourth surface and associated with a sixth thickness ranging from 200 Å to 400 Å;
wherein the n-type layer is located over the fourth surface.

25. A method for making a light-emitting diode device, the method comprising:
depositing an n-type layer so that the n-type layer includes a first surface and is associated with a first thickness;
depositing a first pitted layer on the first surface so that the first pitted layer includes a second surface and is associated with a second thickness ranging from 500 Å to 3000 Å;
forming a first active layer on the second surface so that the first active layer is associated with a third thickness ranging from 10 Å to 20 Å; and
forming a first p-type layer over the first active layer;
wherein:
the n-type layer is further associated with a defect density at the first surface, the defect density ranging from 1×10⁹ cm⁻² to 1×10¹⁰ cm⁻²; and
the first pitted layer is further associated with at least a first plurality of pits, each of the first plurality of pits being related to a first pit size ranging from 500 Å to 3000 Å at the second surface.

26. The method of claim 25 wherein, during and after the process for forming a first active layer on the second surface, the method does not include any process that is performed at a temperature exceeding 980° C.

27. The method of claim 25, and further comprising:
providing a substrate; and
forming a nucleation layer on the substrate so that the nucleation layer includes a third surface and is associated with a fourth thickness ranging from 200 Å to 400 Å.

28. The method of claim 27, and further comprising:
removing the substrate; and
removing the nucleation layer.

29. The method of claim 25 wherein:
the second thickness ranges from 500 Å to 1000 Å; and
the first pit size ranges from 500 Å to 1000 Å at the second surface.

30. The method of claim 25 wherein the defect density ranges from 5×10⁹ cm⁻² to 1×10¹⁰ cm⁻².

31. The method of claim 25, and further comprising:
forming a tunneling layer on the first p-type layer;
depositing a second pitted layer over the tunneling layer so that the second pitted layer including a third surface and associated with a fourth thickness ranging from 500 Å to 3000 Å;
forming a second active layer on the third surface so that the second active layer being associated with a fifth thickness ranging from 10 Å to 20 Å; and
forming a second p-type layer over the second active layer;
wherein the second pitted layer is associated with at least a second plurality of pits, each of the second plurality of pits being related to a second pit size ranging from 500 Å to 3000 Å at the third surface.

32. The method of claim 31 wherein, during and after the process for forming a second active layer on the third surface, the method does not include any process that is performed at a temperature exceeding 980° C.

33. The method of claim 31 wherein:
the fourth thickness ranges from 500 Å to 1000 Å; and
the second pit size ranges from 500 Å to 1000 Å at the third surface.

34. The method of claim 31 wherein the process for forming a tunneling layer includes depositing an InGaN layer doped with Si.

35. The method of claim 31, and further comprising depositing a GaN layer located between the tunneling layer and the second pitted layer.

36. The method of claim 31, and further comprising, after the process for forming a first p-type layer is performed, a growth stop process is performed.

37. The method of claim 36 wherein the growth stop process is performed after the process for forming a tunneling layer is performed.

38. The method of claim 36 wherein the growth stop process is performed before the process for forming a tunneling layer is performed.
